(19) United States
(12) Patent Application Publication
(10) Pub. No.: US 2013/0153938 A1
(43) Pub. Date: Jun. 20, 2013

(54) Light Emitting System

(71) Applicant: Zdenko Grajcar, Crystal, MN (US)

(72) Inventor: Zdenko Grajcar, Crystal, MN (US)

(21) Appl. No.: 13/585,806

(22) Filed: Aug. 14, 2012

Related U.S. Application Data
(60) Provisional application No. 61/570,552, filed on Dec. 14, 2011.

(51) Int. Cl. H01L 27/15

(52) U.S. Cl. 257/88; 257/E27.12

(57) ABSTRACT

A light emitting assembly including a substrate having electrically conductive pathways that electrically connect a plurality of electrical component dies. The said electrical components include at least one light emitting diode engaged along the substrate to form an interface surface between the light emitting diode and the substrate. Therefore the combined and unified vector of thermal conduction from the light emitting diode dies are perpendicular to the interface surface when the combined and unified vector of thermal conduction crosses the interface surface from the light emitting diode die to the substrate.

### CROSS REFERENCE

This application is a continuation of and based upon U.S. Provisional Patent Application Ser. No. 61/570,552 filed Dec. 14, 2011 also entitled LED Lighting Structures and that application is incorporated by reference in full.

### BACKGROUND OF THE INVENTION

This invention relates to a light emitting diode (LED) lighting assembly. More specifically, this invention relates to an LED lighting assembly that minimizes the components of the lighting structure.

Typical LED lighting devices are complex and therefore expensive and difficult to manufacture. This is a result of complex circuitry used to power the LEDs that with the LEDs generates excessive amounts of heat. Thus in existing LED lighting devices, the heat transfer pathway is complex because heat transfer is required for both the LEDs and the LED driving circuitry. An aluminum heat sink generally handles heat dissipation for multiple heat sources such as from the LED holding mechanism and the AC power circuitry. The aluminum is expensive driving the cost to manufacture upwards.

The heat from the different heat sources needs to be moved or channeled to the heat sink. Generally, a heat sink moves the heat away from the electronic components to dissipate the heat. In some devices, around 40% to 60% of the energy going into an LED is dissipated (or wasted) as heat. The driver/power circuitry may be around 80% efficient. In current systems, there are several different locations from which the thermal sources (LED and circuitry) create the heat. Therefore the heat sink included in a LED light is complex.

In addition, the electronics in existing LED lighting devices are large and generally are mounted on a separate structure (e.g., an assembly or substrate) from the structure supporting the LEDs. In existing LED lighting devices, these functions are accomplished through a variety of different sub components were the LEDs are carried on one module, the driver circuitry (regardless of size) is carried on a separate discrete module, the heat sink function is accomplished through several conductive processes, Thus, preexisting devices include multiple discrete components that each separately keep the LEDs, power conditioning, mechanical support (structure) and heat transfer functionalities distinct and separate.

Other devices use additional or distinct mechanical structures or constructs to carry or hold the conditioning circuitry, the heat transfer and the LED elements. Such devices, for example, may include a support onto which the various components (e.g., conditioning circuitry, heat transfer/sink, LEDs, etc) are mounted. In addition, in existing lighting devices, the discrete modules including in the devices are connected to each other using standard wires, connections and/or solder (on the PCB of some designs). Further, the system for diffusion of the light which can be incorporated within a LED lighting device is difficult and inefficient to produce.

Another problem with current LED lighting devices is the cost of components and inventory management of bulbs having different wattage ratings is high. Currently, every light bulb is unique—a 60 W bulb differs from a 100 W in the manufacture of the key components and assembly of the bulb. As a result, such lights bulbs having different wattage ratings cannot necessarily be produced on a same production line. Likewise, creating different bulbs require multiple inventory factors. As a result, separate inventories of lights bulbs of each wattage rating may be needed, resulting in large light bulb inventories.

Another problem exists in current designs where electronics are positioned within or along a heat sink. The electronics also create heat that diffuses in all directions, including back towards the LED substrate/heat spreader. Thus, in existing designs, the LEDs and circuitry are located on different substrates, and the heat produced by the LEDs and circuitry in these designs therefore have different thermal pathways that can work against each other. These designs may need to have multiple thermal pathways for their process, for example in designs that do not place heat-producing driving circuitry (regardless of the circuitry's complexity) and LEDs in a manner such that their vectors of thermal conduction move in different directions.

A further problem with current LED light assemblies is that in order to be configured to be compatible with standard incandescent light-bulbs and light sockets/figures (such as the Edison A19 bulb, as well as other bulbs), the power must be moved by wires to move and return the current from the base to the electronics. Alternatively, the power collected and returned to the socket is completed through the standard base unit, the screw-in portion of a screw-in bulb. These design approaches increase costs and manufacturing complexity (connecting wires to both ends and snaking wires up through some cavity from the base to the electronics).

Thus a principle object of the present invention is to reduce the number of parts in a typical LED lighting device.

Yet another object of the present invention is to reduce manufacturing cost associated with making LED lighting devices.

These and other objects, features and advantages will become apparent from the specification and claims.

### BRIEF SUMMARY OF THE INVENTION

A light emitting assembly having a substrate with electrically conductive pathways that electrically connect a plurality of electrical component dies such as transistors and light emitting diodes. The electrical component dies are engaged along the substrate to form an interface surface between the electrical component dies and the substrate. Therefore, the unified and combined vectors of thermal conduction from the electrical component dies are perpendicular to the plane of the interface surface when the thermal vectors cross the interface surface from the electrical component dies to the substrate.

### BRIEF DESCRIPTION OF THE DRAWINGS

FIG. 1 is an exploded perspective view of a platform assembly of a light emitting assembly;

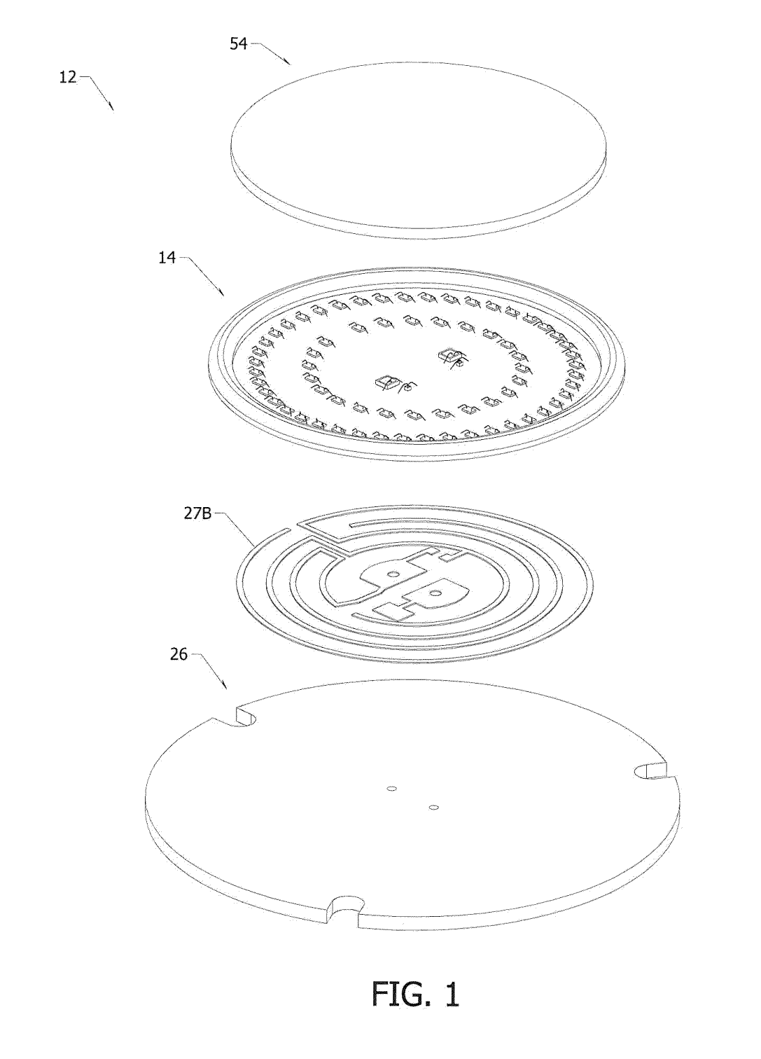

FIG. 2 is a top plan view of an engine of a platform assembly of a light emitting assembly;

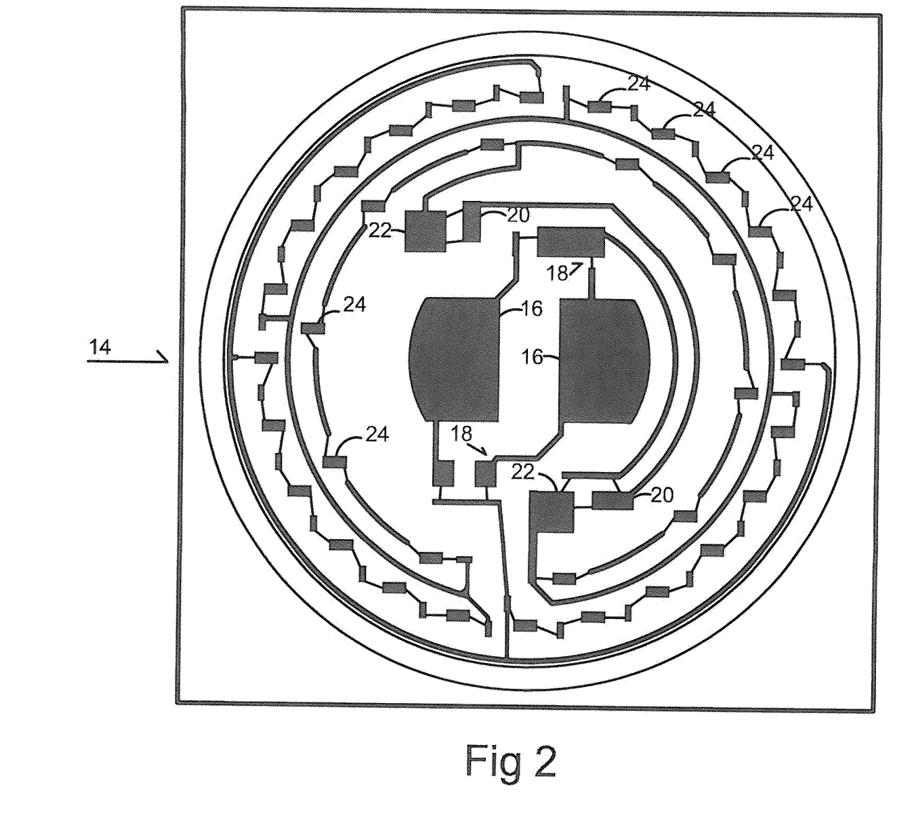

FIG. 3 is a perspective view of a platform assembly of a light emitting assembly;

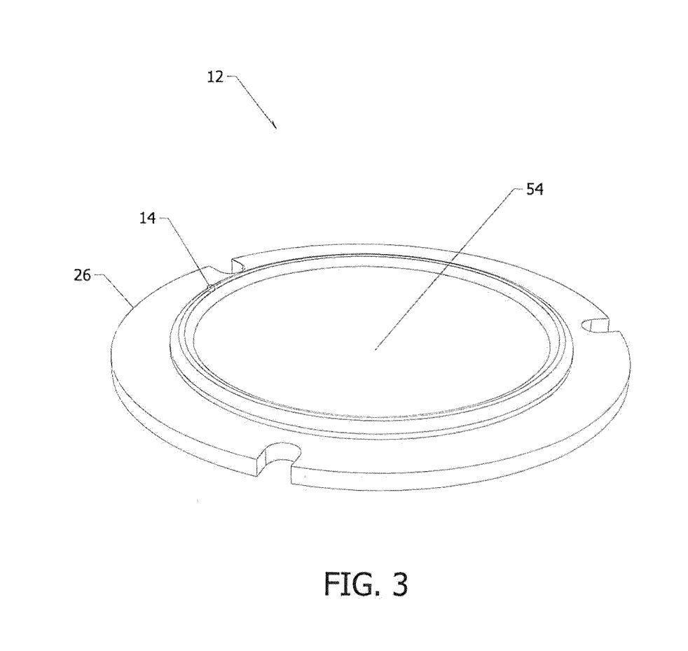

FIG. 4 is a perspective view of a platform assembly with a heat sink of a light emitting assembly;

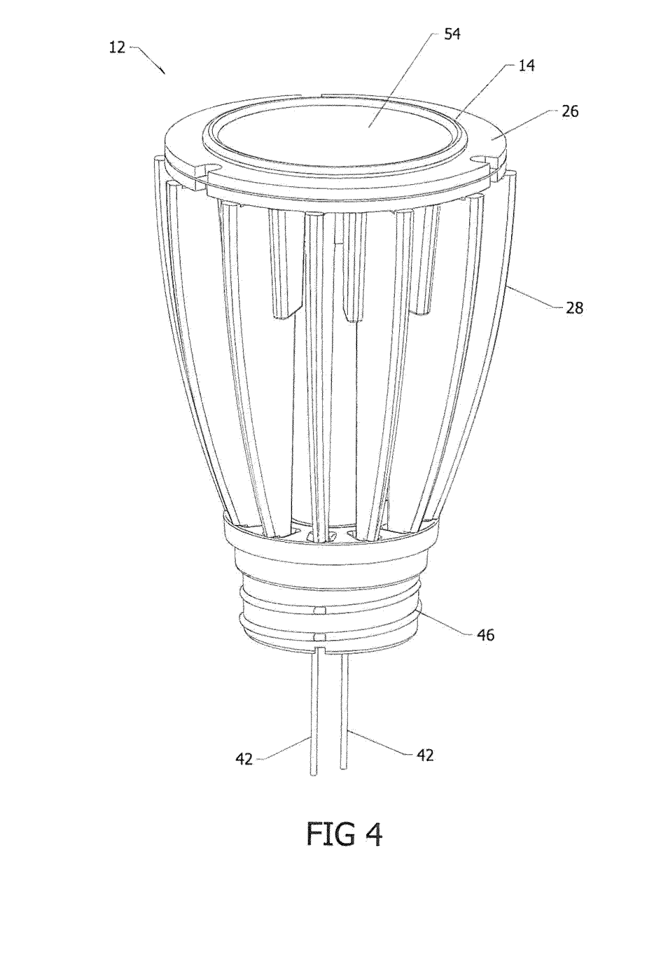

FIG. 5 is a sectional view of a light emitting assembly;

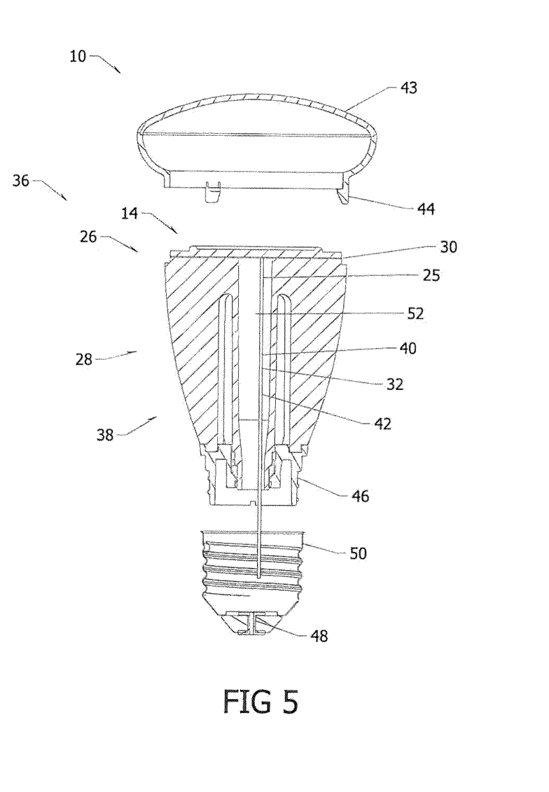

FIG. 6 is perspective view of a light emitting assembly; and

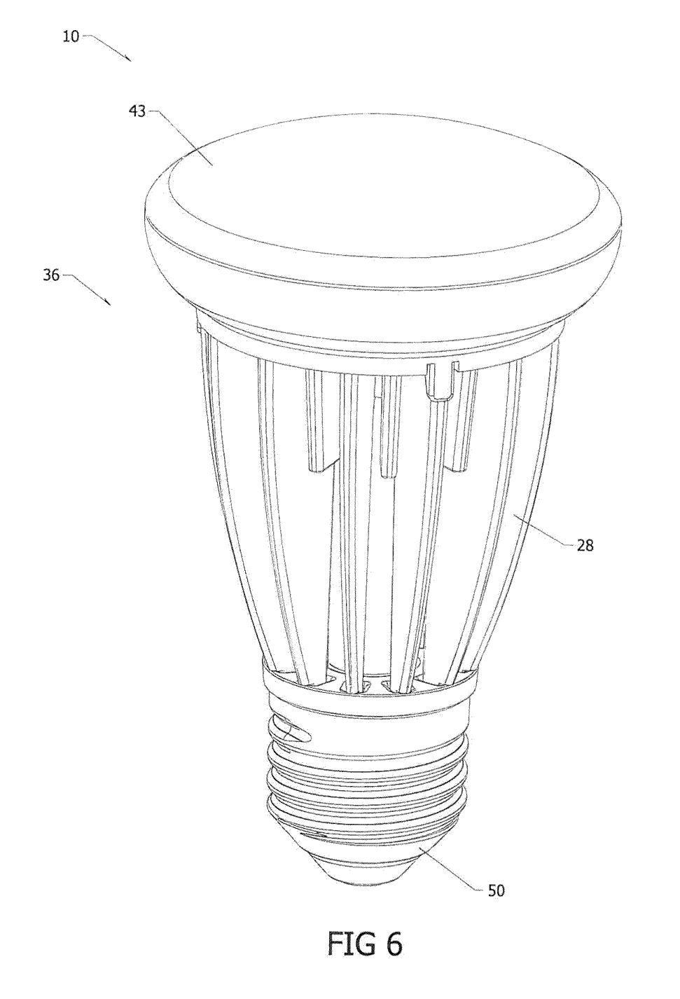

FIG. 7 is a cut away side plan view of the substrate of a light emitting assembly.

### DETAILED DESCRIPTION OF A PREFERRED EMBODIMENT OF THE INVENTION

The figures show a lighting assembly 10 that includes a platform assembly 12 having a common processing engine 14. In one embodiment the common processing engine 14 includes electrical component dies 15 that receive electricity from an AC input 16. In particular a rectifier 18 receives electricity from the AC input 16 and the engine 14 can include protection elements such as a fuse or an MOV and driving elements 20. The driving elements 20 include transistors 22 such as MOSFETs, IGFETs, or the like for powering and dimming a plurality of light emitting diode (LED) dies 24. Further electrical connectors 25 extend from the engine 14 to provide an electrical communication path to other devices.

The processing engine 14 in one embodiment is formed on a substrate 26 that in one embodiment is a printed circuit board. Alternatively the substrate 26 is a hybrid substrate, or takes the form of other types of electric circuits. The substrate 26 can be any shape or size and in one embodiment is circular in shape and the LED dies 24 are arranged in series in any pattern, including arcuately around the circular substrate. Further the transistors 22 and LED dies 24 can be arranged to present a bypass circuit that allows dimming and additional control of the LED dies 24.

The substrate 26 of the improved LED lighting platform can also orient the LED dies 24 to project the light in one or more selected direction(s), without requiring any additional element or secondary carrier or structure upon which the LED dies 24 are placed in order to direct the light. In one example, a single planar element allows for manufacturing using standard electronics manufacturing, and for directing light in a direction away from the plane of the substrate 26 or mechanical support.

Although the above configuration using a single planar element or substrate 26 provides for simpler manufacturing, the substrate 26 or mechanical support need not have a planar configuration, but may instead have any number of shapes. In one example, the mechanical support may be a cube, allowing LED dies 24 to be placed on all six sides, for example, or a sphere with LED dies 24 distributed on the sphere's surface.

In another example, the LED dies 24 may be placed on any number of substructures formed on the single plane (or surface) of the mechanical carrier/support 26. In the example, the single plane (or surface) may have ridges or pyramids built up from the plane, and the LED dies 24 are placed on the ridges or pyramids in order for the light produced by the LED dies 24 to be directed at angles which are not necessarily orthogonal to the plane.

The substrate 26 additionally functions as a heat-conducting or spreading substrate that is formed of a heat conducting material, such as a ceramic material, a material used for hybrids, or the like. Alternatively the materials for this substrate 26 may be any number of technologies, including a simple printed circuit board, or heat conductive plastics with conductive polymers.

The electrical components 15 can be securely mounted directly on the heat-diffusing substrate 26 using an adhesive or other attachment method that conducts heat from the circuitry 20 and LED dies 24 to the heat-diffusing substrate 26. Thus, the elements (i.e., circuits 20 and LED dies 24) can be bonded to the substrate 26 through thermally and electrically conductive material. In this embodiment the heat conduction is accomplished through the thermally conductive epoxy that connects electrical elements to the electrically active substrate 26.

In another embodiment, the electrical components 15 are placed onto the substrate 26 are bonded to the electrically active hybrid/substrate 26 through wire bonds. In yet another embodiment the LED lighting platform 12 can also include several of the components within the substrate 26, for example, by forming a resistor directly into the substrate 26 as a resistive electrical pathway.

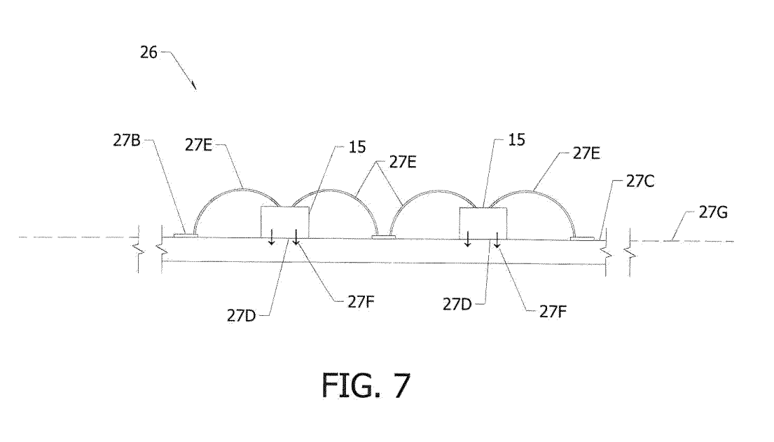

In a preferred embodiment as shown in FIG. 7 the substrate has a plurality of electrically conductive pathways or traces 27B. The substrate additionally functions as a heat spreader. In this embodiment the electrical component dies 15 are engaged to and run along a top surface 27C of the substrate 26 to form an interface surface 27D between each electrical component dies 15 and the substrate 26 and then have electrical connectors 27E to electrically connect the electrical component 15 to the traces 27B. By engaging the top surface 27C of the substrate 26 the vectors of thermal conduction 27F are pointing across the interface surface 27D perpendicular to the interface and top surface 27D and 27C and parallel to one another.

In particular, the vectors of thermal conduction 27F are a combined and unified vector of thermal conduction.

Specifically, a heat transfer vector has both magnitude and directional components such as radiation and heat dissipation or conduction, When the conduction elements of the heat transfer vector are summed together the average vector points downward and perpendicular to the plane 27G defined by the top surface 27C of the substrate 26. This summed and averaged vector is considered a combined and unified vector of thermal conduction. As a result of this combined and unified vector of thermal conduction crossing the top surface 27C perpendicular to the surface 27C efficiency of moving heat from the top surface 27C of the substrate 26 through the substrate 25 is maximized.

In addition to moving heat more efficiently from the electrical component dies 15 through the substrate 26, this design allows the electrical component dies to lie on a single plane 27G along with the traces 27B. Thus all of the electrical component dies 15 of the assembly 10 lie on the same plane 27G greatly reducing the size of the entire assembly 10 allowing for more practical functionality for the assembly 10. Further, as a result of the design, all of the heat generated by the assembly 10 lies only on the top surface 27C of the substrate 26 again increasing efficiencies, allowing for a more compact assembly 10 and providing greater ease in manufacturing the assembly 10.

An integrated heat sink 28 optionally can be provided secured to the substrate 26. In this manner the substrate 26 functions as a heat diffuser that diffuses heat from circuitry to the sink 28. The LED lighting platform 12 thus provides an integrated heat sink 28 that carries away heat generated by both the common processing engine 12 and the LED dies 24. In one embodiment the heat-conductive substrate 26 is mounted on the heat sink 28. Therefore, the integrated platform 12 not only provides for the lighting support, but also handles the heat sink function by drawing the heat away from the electrical component dies 15, spreading the heat out across the substrate plane 27G, and/or allowing the heat to be pulled down into the heat sink 28.

In embodiments utilizing a heat sink 28 a thermally and electrically conductive adhesive 30 is provided to move thermal vectors in the same direction. Specifically, heat does not dissipate well up into a first quadrant above the plane 27G of the lighting assembly 10 (i.e., above the LED die into the bulb capacity—air is a thermal insulator, the heat can be drawn down through the thermally conductive epoxy). Therefore, a design directing vectors of thermal conduction in the same direction (all circuitry is co-located) downwardly into at second quadrant below the plane 27G is presented. In particular, a combined and unified vector of thermal conduction has a direction that points away from the substrate 26 (the heat being created by the LED dies 24 on the substrate 26 which is also serving as a heat spreader) toward the second quadrant and has a magnitude that is reduced as it proceeds through the heat sink 28.

The combined and unified vector of thermal conduction 27F, having all thermal gradients pointing/moving away from the lighting plane 27G, provides a way to block other components from being able to source all the heat from the same plane (i.e., have the circuitry and LED dies being together). Therefore, in the instant design, the electrical component dies 15 have thermal vectors that point in the same direction and the thermal resistance is therefore optimized to handle the heat in this same manner.

The single vector heat direction makes it easier for the dissipation of the heat from the electrical components 15, the simplification of the entire lamp structure, to obviate the need for any cavities, to allow for decreased amount of materials to be used, and to lessen the need for moving heat to the heat sink 28. This is, in part, facilitated by the plane LED platform 12 being attached with the greatest surface area for conducting heat away from the elements (heat spreader) towards the heat sink's receiving or transfer portion of the sink 28 (the top of the sink).

The heat sink 28 may have different thermal conductive properties along the heat sink 28. That is, where the magnitude of the vector is greatest (e.g., right at the transfer point from the LED Platform and the thermal transfer receiver of the heat sink, near the attachment point of the heat sink 28 to the heat conductive substrate 26, and/or in a part of the heat sink 28 that is closest to the electrical component dies 15), the heat sink 28 may need to dissipate the greatest amount of heat. In order to diffuse more heat, the heat sink 28 may be formed such that the heat sink 28 has more material or heat fins in areas in which greater diffusion is needed.

Alternatively, the areas of the heat sink 28 responsible for more diffusion may be formed of materials with superior thermal conduction and dissipation properties. Because the heat vector is in a single direction, as the vector magnitude is reduced (some of the heat is already dissipated) in areas located further from the heat generating LED dies and circuitry, the performance of the heat sink 28 need not be as good, and the heat sink 28 may be formed with less material (e.g., a taper in the heat sink), or materials having lower thermal conduction and dissipation properties.

In another embodiment for the heat transfer, given the uniform vector, an active element for heat transfer cooling may be used. The described embodiment can include a square pipe (or other conduit for cooling agent) which has the LED Platform 12 attached or integrated along one contact point to the conduit. Within the conduit, a cooling agent, such as water, may flow to pull the heat down and/or into the conduit and the cooling agent.

In one embodiment the heat sink 28 is made of fly ash. In particular fly ash is inexpensive in cost and lower weight. While not as an effective heat sink 28 as other more expensive materials, because of the design of the platform 12 a lower quality heat sink 28 can be used. Still, the heat sink design using fly-ash needs to factor in the worst-case tolerance for a lot of low quality fly ash materials, to ensure that the heat sink performance always meets the minimum required performance.

In another embodiment a conductor 32 is integrated or embedded directly into the heat sink 28. Alternatively the heat sink 28 has one or more conductors 32 embedded into the heat sink structure. These conductors 32 can be of different types, including insulated wires, insulated conductor sticks, etc. If the heat sink material is thermally conductive, but not electrically conductive, the conductors need not be insulated. By having conductors 32, the increases reliability of the platform 12 is increased while lowering overall cost of the lighting assembly 10. Further, an electrically-active heat sink simplifies manufacturing (assembly) of the lighting assembly 10. In addition, the heat sink 28 may be fabricated with the conductors 32 within its volume, such as by using injection molding or, if polymers are used, by using selective conductive polymers that are extruded.

Thus, by utilizing conductors 32 that are integrated or embedded into the heat sink 28 electrically active electrical connectors 25 or terminals protrude at the surface of the heat sink 28. As a result the electrical connectors 25 provide a simple connection point for auxiliary devices 36 to provide an electric communication path between the engine 14 and auxiliary devices 36.

In one embodiment the auxiliary device 36 is a bulb assembly that includes the heat sink 28 and has a base unit 38 with connection elements 40 such that a connection between the engine 14 and the bulb assembly 36 is provided. Thus the base unit 38 contacts the base 41 of the light bulb such that connection can be accomplished more simply, such as snapping on the base unit 38 and/or snapping on the LED platform 12. Any number of connections may be accomplished to ensure electrical continuity and reliability, whether conductive epoxy, wire connections or connectors (e.g., as used in the automotive/electronics the force hold), laser or ultrasonic _{welding,} et

Further the bulb assembly 36 can be standardized as a single assembly for multiple functions. Specifically, a single LED platform 12 has a selectable brightness or wattage rating. The single LED platform 12 may thus be able to selectively operate as a 100 W bulb, as a 60 W bulb, or as another appropriate type/brightness/wattage of bulb. The LED platform 12 can therefore serve as a common element for many different brightnesses or wattage ratings. The brightness or wattage rating of the bulb assembly 36 is set or selected at an end stage of the manufacturing process. In other words, to save costs in manufacturing, a single LED platform 12 is always built that can operate at a selectable brightness or wattage rating.

To save costs in process inventory, only one type of sub assembly may need to be created, since all bulbs of the LED platform 12 have the same sub assembly. Additionally, to simplify inventory management, bulb assemblies 12 can be pre-built up to the point of having the brightness/wattage rating set or selected, and the manufacturing process can be completed once the desired brightness/wattage rating is known. As such, one LED platform 12 is built that can provide illumination brightness or wattage rating for a wide range of bulb equivalents, such as a LED platform that can be tuned or configured to provide a 40 W, 60 W, 75 W and 100 W equivalent bulb.

Each LED platform 12 thus includes components required by all of the possible brightness/wattage ratings. Once a brightness is selected, some of the LED dies 24 of the LED platform 12 may not be powered in some lower illumination bulbs (though these LED dies are nonetheless included in the standard LED platform).

The LED platform 12 may be entirely assembled except for the light diffuser, and may be configured immediately prior to the final assembly step. The LED platform 12 may be configured by way of setting fuse links to enable or disable certain LED dies 24 in the LED platform to change the brightness or, by way of some point resistor (or some more power efficient means) change the brightness of all the LED dies 24 (such that all LED dies are lit, but the LED dies are lit at a lower brightness).

The bulb assembly 36 in one embodiment includes a sleeve element 40 or stem that carries wires 42 from the base unit 38 to the platform assembly 12. In one embodiment the wires 42 are the conductors 32 within the heat sink 28. The lens 43 or bulb of the bulb assembly 36 is connected or secured to the heat sink 28 and or substrate 26 through any connection means. In one embodiment the connection is a friction connection that provides for either locking or crimping. For example, a connection assembly 44 such as a pop in receptacle at the top of the sleeve element 40 is also provided so that the lighting engine 14 can be simply friction fit into the top of the stem containing the wires. This structure may eliminate the need for glue on top of the cooling fins and allow for the lighting assembly to be machine assembled, using a tool to “punch on” the lighting engine in line, like bottle caps being put on a bottle. Alternatively clips built into the edges of the diffuser, may allow the top to be “popped on” after the engine is in place, again eliminating the need for glue. The cooling fins may be tooled in such a way as to receive the clips in a locking, one way form, without having to orient the diffuser to specific location on the rim of the fins.

The integrated sleeve element 40 or shaft includes the base components, including a threaded section 46 (the screw-in of the screw-in bulb) that mates with a traditional socket and the wiring 42 or mechanical bridge to the LED platform 12. In this manner the wiring can be physically and electrically connected to the base mechanics 48 or wires of a standard bulb base 50 to provide the typical connection to a standard socket.

The integrated sleeve element 40 or shaft can also be inserted up and through a cavity 52 within the heat sink 28, but is still a distinct component from the heat sink 28. In particular, because the heat sink 28 includes embedded conductors 32 and wiring, the heat sink 28 remains solid.

A phosphor 54 is placed over the lighting platform 12 to provide a conversion material that encapsulates the LED dies 24 and other electrical component dies 15. Because the phosphor 54 or optically clear material also encapsulates the electrical component dies 15 this eliminates the need for electrical component die packaging. The phosphor 54 also converts color from blue LED dies 24 into white. All LED dies 24 in the lighting platform 12 are mounted on a single substrate 26 (e.g., on a surface of a planar substrate), and the phosphor 54 is applied over the substrate 26 (or surface of the substrate) having the LED dies 24 thereon. As such, the phosphor 54 can be easily applied to all LED dies 24 in the lighting platform 12 in a single processing step, without requiring each individual LED to have phosphor separately applied to the LED. Thus the conversion phosphor layer 54 covers a substantial portion of the substrate 26 including the electrical component dies 15, such that all of the LED dies 24 are covered by the conversion phosphor 54.

In operation the common processing engine 14 of the lighting assembly 10 functions to drive the platform assembly 12 and performs current/voltage conditioning. Further the processing engine 14 functions to dim and otherwise control the platform assembly 12. Also, the substrate 26 acts as a heat transferring device to cool the platform assembly 12. Further the engine 14 is both mechanically and electrically attached to the substrate 26. A heat sink 28 also acts to convey heat away from circuitry which is done by providing a heat vector moving in a single direction.

In addition, by having a common processing engine 14, the engine 14 presents electrical contacts 25 for attaching a bulb assembly 36 or other light source or circuit to provide a connection to the AC input 16 to produce light from the LED dies 24. Specifically the bulb assembly 36 can be frictionally fit onto the platform 12 to provide a traditional looking lighting assembly 10.

Thus presented is a common processing engine 14 that integrates disparate functions to be performed by one common processing engine 14. These functions include AC power conditioning, heat transfer functions (cooling), mechanical attachment, electrical attachment/connections, light diffuser, structural integrity, light configuration/identity, distributed and returned power, which perform a multitude of functions necessary for the efficient operation of the LED lamp 10 (i.e., conditioned power, produced light, etc.), are such that all the related functions for an LED lamp 10 are integrated into a single light producing multifunction device. The integrated functionality provides a common assembly that goes beyond the integration of transistors and power to include the output of heat transfer away from the circuits and the LED dies 24.

The substrate 26 provides mechanical support for electrical components 15. The improved LED lighting platform 12 can include a common physical platform or substrate 26 that provides heat sink/transfer functionality, light diffusing functionality, mechanical attachment and structural integrity (e.g., to attach the improved LED lighting platform to a support, to a socket, wire, or other source of electrical power, and/or to attach a bulb/LED or other light source to the platform), and/or the like. In one example, the mechanical support takes the form of a substrate 26 on which LED dies 24 are formed.

Therefore, the improved. LED lighting platform 12 uses a single structure that integrates the mechanical support into a single device or mechanism. For example, the single structure may be a substrate 26 having formed, on its surface or within its volume, the circuitry of the common processing engine 14. The substrate 26 may thus provide the physical structure of the lighting platform 12, and include attachments, mounts, or the like provided as part of the physical structure.

By using this single structure or mechanism, the manufacture (at least now for a single plane device/mechanism) can be accomplished using existing production equipment for hybrids, such as pick-n-place and wire-bond technologies. Hybrids can include hybrid circuits and substrates, printed circuit boards, and other physical media used to mount circuits or components. The hybrids can have electrical traces formed on their surface or in their volume, for electrically interconnecting circuits or components mounted on the hybrid.

Further, the improved LED lighting platform 12 uses any number of connection concepts, mechanical fixation, welding, thermally and electrically conductive adhesive (in a preferred embodiment) to connect the electrical components 15 to an electrically active substrate 26. This approach serves multiple purposes and simplifies the design. For example, the approach ensures that both the mechanical (fixation) and electrical (power) connections are shared and established through the single connection action. The epoxy is what bonds the element to the substrate.

As a result of the design of the improved lighting assembly 10, instead of having several different manufacturing approaches for the various components in other lights, the improved lighting platform 12 can use a common manufacturing approach for all the different components (AC circuitry, LED dies, etc.) that can be used to expedite and simplify manufacturing using the same manufacturing equipment with a silicon die and the same manufacturing techniques/technologies. Mounting of all the different components can thus be accomplished using the same technologies.

Surface mounting results in significant resistance to failure through shock, vibration or rough handling. In one instance, multiple traces (wires in the substrate) can be used (e.g., in a multi-layer substrate) so as to provide electrical connections through the substrate between two or more elements connected to the substrate. The improved LED lighting platform 12 can incorporate all the technology into the silica in die form, for example by using AC conditioning circuitry. The incorporation of the technology in die form may be made possible by having no reactive components (inductors, capacitors) or voltage shifting technologies (transformers) included in the circuitry.

Further, as a result of the simplicity of the platform 12 a bulb assembly 36 can be frictionally connected to the platform to present a traditional looking, aesthetically pleasing lighting assembly 10. Thus, at the very least all of the stated objects have been met.

1. A light emitting assembly comprising:
an AC input;
a substrate having electrically conductive pathways that electrically connect a plurality of electrical component: dies;
said electrical component dies including at least one light emitting diode die engaged along the substrate to form an interface surface between the light emitting diode die and the substrate;
said electrical component dies including driving component dies including at least one transistor;
said electrical component dies providing a driving electrical input for the light emitting diode die from the AC input;
wherein a combined and unified vector of thermal conduction from the light emitting diode die is perpendicular to the interface surface when the combined and unified vector of thermal conduction crosses the interface surface from the light emitting diode die to the substrate; and
said substrate mounted to a heat sink that draws heat away from the electrical dies.

2. The light emitting assembly of claim 1 wherein the substrate comprises the electrically conductive pathways and a heat spreader.

3. The light emitting assembly of claim 1 wherein the electrical component dies are encapsulated by a phosphor.

4. A light emitting assembly comprising:
an AC input;
a substrate having electrically conductive pathways on a top surface;
a plurality of electrical component dies, including both driving component dies and at least one light emitting diode die in electrical communication with the electrically conductive pathways;
said driving component dies including at least one transistor;
said electrical component dies providing a driving electrical input for the light emitting diode die from the AC input; and
wherein the driving component dies, a rectifier and the light emitting diode die lie on the same plane.

5. The light emitting assembly of claim 4 wherein the plane is the top surface of the substrate and wherein each of the driving component dies, rectifier and light emitting diode die engages the top surface.

6. The light emitting assembly of claim 5 wherein no electrical component dies of the light emitting assembly lie in a different plane from the plane formed by the top surface of the substrate.

7. A light emitting assembly comprising:
an AC input;
a platform assembly having a substrate with electrically conductive pathways therein;
a plurality of electrical components electrically connected via the conductive pathways and attached to a top surface of the substrate;
said electrical components providing a driving electrical input for a plurality of light emitting diodes from the AC input;
wherein the plurality of electrical components includes a rectifier;
a heat sink connected to the platform assembly; and
wherein heat generated only at or above the top surface of the substrate is conveyed to the heat sink.

8. The light emitting assembly of claim 7 wherein the substrate is made of a ceramic material.

9. The light emitting assembly of claim 7 wherein the substrate is a printed circuit board.

10. The light emitting assembly of claim 7 wherein an adhesive mechanically connects the substrate.

11. The light emitting assembly of claim 7 wherein a combined and unified vector of thermal conduction moves from a first quadrant above a plane at the top surface of the substrate to a second quadrant below the top surface of the substrate.

12. The light emitting assembly of claim 7 wherein the heat sink is made of fly ash.

13. The light emitting assembly of claim 7 wherein at least one conductor is embedded into the heat sink.

14. The light emitting assembly of claim 7 further comprising a phosphor applied over the substrate.

15. The light emitting assembly of claim 7 wherein the heat generated at the top surface of the heat sink is the only heat generated by the light emitting assembly.

16. The light emitting assembly of claim 7 wherein the plurality of electrical components are a plurality of electrical component dies that engage the top surface of the substrate.

17. The light emitting assembly of claim 16 wherein the electrical component dies are positioned adjacent the electrically conductive pathways on the top surface of the substrate.
